(19) United States
(12) Patent Application Publication
(10) Pub. No.: US 2014/0311564 A1
(43) Pub. Date: Oct. 23, 2014

(54) ZNMGO FILM AND METHOD OF MANUFACTURING ZNMGO FILM

(71) Applicants: Ryosuke Maekawa, Tahara-shi (JP); Hiroki Awano, Susono-shi (JP); Tomoya Matsunaga, Susono-shi (JP); Yuichiro Takeda, Susono-shi (JP); Takenobu Sakai, Miyoshi-shi (JP)

(72) Inventors: Ryosuke Maekawa, Tahara-shi (JP); Hiroki Awano, Susono-shi (JP); Tomoya Matsunaga, Susono-shi (JP); Yuichiro Takeda, Susono-shi (JP); Takenobu Sakai, Miyoshi-shi (JP)

(73) Assignee: TOYOTA JIDOSHA KABUSHIKI KAISHA, Toyota-shi, Aichi-ken (JP)

(21) Appl. No.: 14/354,000

(22) PCT Filed: Oct. 25, 2012
(86) PCT No.: PCT/IB2012/002138

§ 371 Date: Apr. 24, 2014

(30) Foreign Application Priority Data
Oct. 27, 2011 (JP) 2011-235630

(51) Int. Cl. H01L 31/18; H01L 31/0256

(52) U.S. Cl. CPC H01L 31/18; H01L 31/0256
USPC 136/256; 427/376.2

(57) ABSTRACT

A method of manufacturing a ZnMgO film includes the steps of in order: dissolving a zinc material and a magnesium material in an aqueous ammonia solution having a temperature at which, in an aqueous solution state diagram which represents ion concentrations on a vertical axis and pH on a horizontal axis, a line a demarcated by a region where Zn(OH)₂ precipitates and a region where ZnO₂²⁻ can exist is positioned on a low pH side from a line β demarcated by a region where magnesium ions can exist and a region where Mg(OH)₂ precipitates, and adjusting the pH of the aqueous ammonium solution and the zinc ion concentration and magnesium ion concentration in the aqueous ammonia solution within a region lying between the line a and line β; elevating the temperature of the aqueous ammonia solution to a temperature at which Zn(OH)₂ and Mg(OH)₂ precipitate; and firing the precipitate.

### BACKGROUND OF THE INVENTION

1. Field of the Invention

The invention relates to a ZnMgO film and to a method of manufacturing the film.

2. Description of Related Art

Solar cells have a small carbon footprint per unit of power generated and require no fuel to generate power. Accordingly, they are expected to serve as an energy source that helps to check global warming. The solar cells in practical use today are predominantly single junction solar cells which use monocrystalline silicon or polycrystalline silicon and have a pair of pn junctions. However, such single-junction solar cells have a low light absorptance and a low theoretical photoelectric conversion efficiency. Hence, research on solar cells capable of improving these characteristics is actively being carried out today.

One such solar cell is the compound thin-film solar cell. Compound thin-film solar cells conserve natural resources, can easily be mass-produced, and have the potential to greatly improve the conversion efficiency. Recently, ZnMgO has attracted attention as the buffer layer in compound thin-film solar cells and as a light-emitting device material. ZnMgO has hitherto been produced by vapor phase film-forming processes using sputtering technology and the like. Efforts continue to be made to enlarge the band gap by increasing the amount of magnesium added. However, for a number of reasons, including the high cost of the equipment used in vapor phase film-forming processing and the difficulty of completely covering the underlying material which has an uneven surface on account of flow by the starting material in a single direction, it is thought to be desirable to produce ZnMgO by a liquid phase film-forming process.

For example, a technique for producing ZnMgO by a liquid phase film-forming process is disclosed in the Journal of Materials Science (Germany), 41, No. 4, 1269-1271 (2006).

When ZnMgO is used in compound thin-film solar cells such as copper indium gallium diSelenide (CIGS) solar cells which use a compound of copper, indium, selenium and gallium, in order to achieve a form in which, at the time of pn junction interface formation, electrons are capable of migrating to the p layer side, and also a form in which electrons generated by light absorption are capable of migrating to the electrode, it is desired that the amount of magnesium added relative to zinc be set to at least 30 mol %. However, in conventional liquid phase film-forming methods such as that disclosed in the Journal of Materials Science, the upper limit in the amount of magnesium added relative to zinc has been about 10 mol %.

### SUMMARY OF THE INVENTION

It is therefore an object of this invention to provide a method of manufacturing a ZnMgO film in which the amount of magnesium added relative to zinc may be set to at least 30 mol %. Another object of the invention is to provide a ZnMgO film in which the amount of magnesium added relative to zinc is at least 30 mol %.

A method of manufacturing a ZnMgO film according to a first aspect of the invention includes the steps of: dissolving a zinc material and a magnesium material in an aqueous ammonia solution having a temperature at which, in an aqueous solution state diagram which represents a zinc ion concentration and a magnesium ion concentration on a vertical axis and represents pH on a horizontal axis, a line α demarcated by a region where Zn(OH)₂ precipitates and a region where ZnO₂²⁻ can exist is positioned on a lower pH side than a line β demarcated by a region where magnesium ions can exist and a region where Mg(OH)₂ precipitates, and adjusting the pH of the aqueous ammonium solution and the zinc ion concentration and magnesium ion concentration within the aqueous ammonia solution so as to obtain a state within a region lying between the line α and the line β; elevating the temperature of the aqueous ammonia solution to a temperature at which Zn(OH)₂ and Mg(OH)₂ precipitate after the pH and the ion concentrations are adjusted; and firing the precipitate after the temperature of the aqueous ammonia solution is elevated.

In the first aspect of the invention, by dissolving suitable amounts of a zinc material and a magnesium material in an aqueous ammonium solution having a pH which, in a temperature environment where the line α is positioned on the lower pH side than the line β, has been adjusted so as to fall in a region lying between the line α and the line β, ZnO₂²⁻ and Mg²⁺ can be made to exist within the aqueous ammonia solution.

After having placed the solution in a state where both of these ions are present, elevating the temperature of the aqueous ammonia solution shifts the line β to the low pH side, making it possible to induce the precipitation of Mg(OH)₂. In addition, elevating the temperature of the aqueous ammonia solution causes ammonia to volatilize, making it possible to lower the pH of the aqueous ammonia solution. Because the aqueous ammonia solution can be set in a state on the low pH side of the line α, it is possible to induce the precipitation of Zn(OH)₂. By thus causing Zn and Mg which have been present in an ionic state to precipitate as, respectively, Zn(OH)₂ and Mg(OH)₂ under a similar timing, the zinc is easily replaced with magnesium, making it possible to set the amount of magnesium addition relative to zinc to at least 30 mol %. Once the Zn(OH)₂ and Mg(OH)₂ have been induced to precipitate, it is then possible to produce a ZnMgO film by firing the precipitate and inducing a dehydration reaction.

In the first aspect of the invention, it is preferable for the temperature at which the line α is positioned on the lower pH side than the line β to be at most 25° C. By setting the temperature of the aqueous ammonia solution in the temperature and pH adjusting step to at most 25° C., it is possible to widen the region lying between the line α and the line β. As a result, having ZnO₂²⁻ and Mg²⁺ both present within the aqueous ammonia solution becomes easier, which makes it easier to manufacture a ZnMgO film having an amount of magnesium addition relative to the zinc of at least 30 mol %.

A ZnMgO film according to a second aspect of the invention having a ratio of (100) x-ray diffraction intensity to (002) x-ray diffraction intensity of at least ½, and a ratio of (101) x-ray diffraction intensity to (002) x-ray diffraction intensity of at least ½.

The ZnMgO film, which was produced by the manufacturing method according to the first aspect of the invention, and, wherein the amount of magnesium addition relative to the zinc is at least 30 mol %, has a ratio of (100) x-ray diffraction intensity to (002) x-ray diffraction intensity of at least ½, and a ratio of (101) x-ray diffraction intensity to (002) x-ray diffraction intensity of at least ½. Hence, by satisfying such x-ray diffraction intensity ratio conditions, it is possible to obtain a ZnMgO film wherein the amount of magnesium addition relative to zinc has been set to at least 30 mol %.

According to the first aspect of the invention, there is provided a ZnMgO film manufacturing method which is able to set the amount of magnesium addition relative to zinc to at least 30 mol %.

According to the second aspect of the invention, there is provided a ZnMgO film having an amount of magnesium addition relative to zinc of at least 30 mol %.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a state diagram of an aqueous solution containing zinc ions and magnesium ions;

FIG. 2 is another state diagram of an aqueous solution containing zinc ions and magnesium ions;

FIG. 3 is yet another state diagram of an aqueous solution containing zinc ions and magnesium ions;

FIG. 4 is a further state diagram of an aqueous solution containing zinc ions and magnesium ions;

FIG. 5 is a flow diagram illustrating the inventive method of manufacturing a ZnMgO film;

FIG. 6 is a diagram showing the results of x-ray diffraction measurement;

FIG. 7 is a graph showing the relationship on the ZnMgO film between the mole fraction Mg/(Zn+Mg) and the diffraction angle 2 θ at which the (002) peak was confirmed in x-ray diffraction measurement;

FIG. 8 is a chart showing the results of x-ray diffraction measurement on a ZnMgO film produced by sputtering;

FIG. 9 is a graph showing the relationship between the light energy and the square of the light absorption coefficient; and

FIG. 10 is a graph showing the relationship on the ZnMgO film between the mole fraction Mg/(Zn+Mg) and the band gap.

### DETAILED DESCRIPTION OF EMBODIMENTS

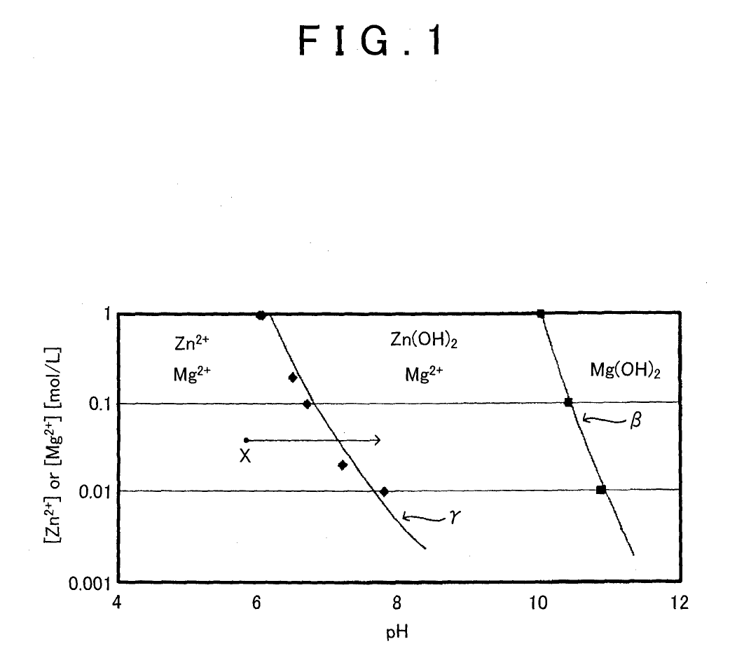

FIG. 1 is a state diagram of an aqueous solution containing zinc ions and magnesium ions at 25° C. The vertical axis in FIG. 1 represents the zinc ion concentration (mol/L) and the magnesium ion concentration (mol/L), and the horizontal axis represents the pH. A line β demarcated by a region where magnesium ions can exist and a region where Mg(OH)₂ precipitates out of solution (which line is referred to below as simply “line β”) and a line γ demarcated by a region where zinc ions can exist and a region where Zn(OH)₂ precipitates out of solution (which line is referred to below as simply “line γ”) are shown in FIG. 1. FIG. 1 is a diagram which shows that zinc ions can exist on the low pH side of line γ, that Zn(OH)₂ precipitates out on the high pH side of line γ, that magnesium ions can exist on the low pH side of line β, and that Mg(OH)₂ precipitates out on the high pH side of line β.

When a ZnMgO film is produced by a conventional liquid phase film-forming method, the ZnMgO film has typically been produced via the steps of, for example, dissolving zinc chloride and magnesium chloride in an aqueous solution of hydrochloric acid, then adding ammonia water thereto to coprecipitate zinc and magnesium. This method is described here while referring to FIG. 1. The ZnMgO film is produced via a step wherein, for example, by increasing the pH, a solution in the state indicated by X in FIG. 1 crosses line γand is rendered into a state where Zn(OH)₂ precipitates out. Hence, in a conventional liquid phase film-forming process, by changing from a low pH state to a high pH state, line γ was crossed and the precipitation of Zn(OH)₂ was induced. However, as shown in FIG. 1, even when the pH is increased and Zn(OH)₂ is caused to precipitate out, magnesium can exist in an ionic state on the low pH side of line β. To induce Mg(OH)₂ to precipitate out of solution, the pH of the solution must be further increased to the high pH side of line β. Because it has been difficult with conventional processes to induce at a similar timing the precipitation of zinc and magnesium existing in an ionic state, only a small amount of magnesium is taken up during the precipitation of Zn(OH)₂. This is presumably why the upper limit in the amount of magnesium addition relative to zinc has been only about 10 mol %. Even in processes based on electrolytic precipitation, the amount of magnesium addition relative to zinc has been limited to about 7.7 mol % for similar reasons.

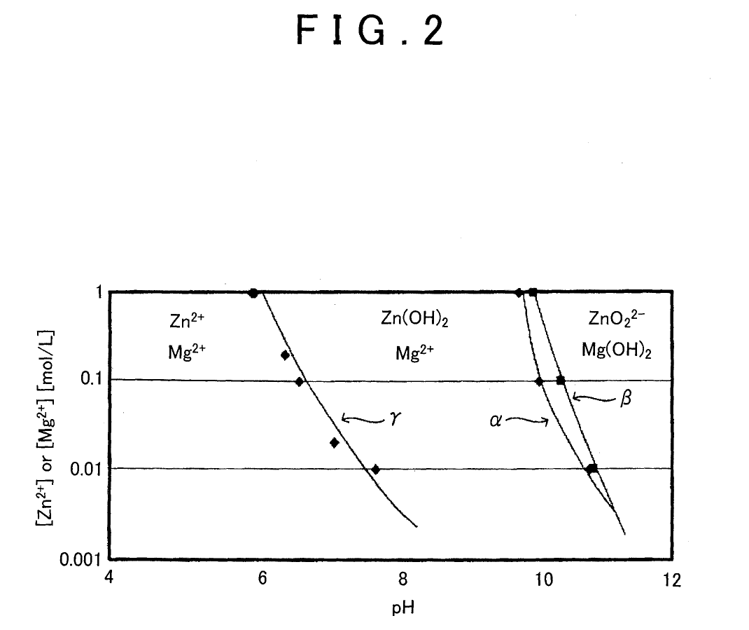

When the pH is increased further from the region where Zn²⁺ precipitates out as Zn(OH)₂, the zinc can exist in the state of ZnO₂²⁻. FIG. 2 shows an aqueous solution state diagram obtained by adding to the aqueous solution state diagram in FIG. 1 a line α demarcated by a region where Zn(OH)₂ precipitates out of solution and a region where ZnO₂²⁻ can exist (which line is referred to below as simply “line α”). FIG. 2 is a diagram which shows that zinc ions can be exist on the low pH side of line γ, that Zn(OH)₂ precipitates out of solution on the high pH side of line γ and the low pH side of line α, that ZnO₂²⁻ can exist on the high pH side of line α, that magnesium ions can exist on the low pH side of line β, and that Mg(OH)₂ precipitates out of solution on the high pH side of line β.

As shown in FIG. 2, on the high pH side of line α and the low pH side of line β (the region lying between line α and line β), ZnO₂²⁻ and magnesium ions can both be present. Hence, after controlling the temperature, pH, zinc ion concentration and magnesium ion concentration of the aqueous solution so as to satisfy the conditions of the region lying between line α and line β, if the Zn(OH)₂ and the Mg(OH)₂ can be induced to precipitate out at similar timings, it should be possible to increase the amount of magnesium addition relative to zinc more than previously possible.

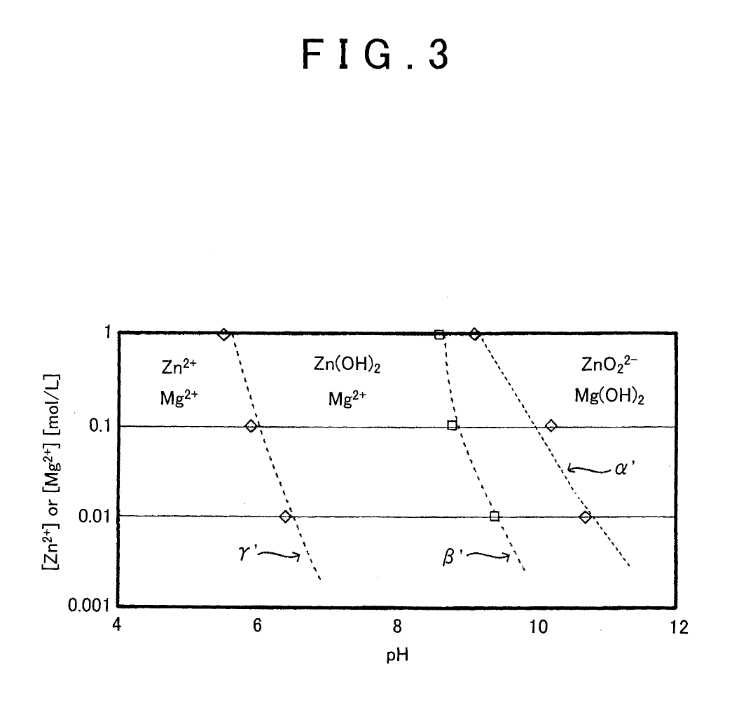

As a result of intensive investigations, the inventors have discovered the state diagram of an aqueous solution containing zinc ions and magnesium ions at 60° C. to be as depicted in FIG. 3. FIG. 3 shows a line α′ corresponding to line α, a line β′ corresponding to line β, and a line γ′ corresponding to line γ, each of which have shifted toward the low pH side with elevation in the temperature of the aqueous solution. FIG. 3 is a diagram showing that zinc ions can exist on the low pH side of line γ′, that Zn(OH)₂ precipitates out on the high pH side of line γ′ and the low pH side of line α′, that ZnO₂²⁻ can exist on the high pH side of line α′, that magnesium ions can exist on the low pH side of line β′, and that Mg(OH)₂ precipitates out on the high pH side of line β′.

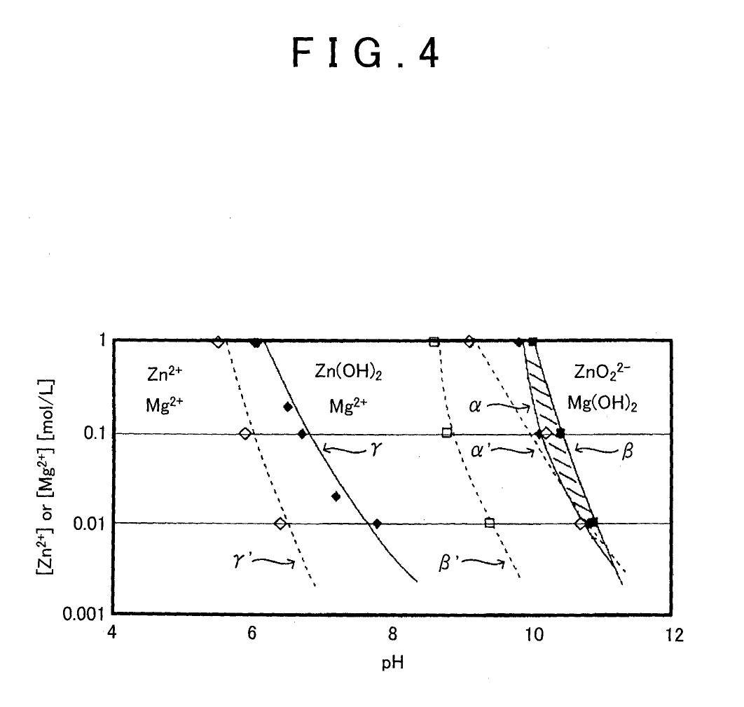

FIG. 4 shows an aqueous solution state diagram obtained by adding line α′, line β and line γ′ to FIG. 2. In FIG. 4, the region lying between line α and line β is shaded. From FIGS. 2 to 4, when the temperature of the aqueous solution is 25° C., line a is present on the low pH side of line β, whereas line α′ is present on the high pH side of line β′. Hence, although both line α and line β shift to the low pH side with a rise in temperature, the degree of shift to the low pH side was found to be larger for line β than for line α. From these results, by elevating the temperature of the aqueous solution, it is possible to markedly shift line β to the low pH side.

As a result, it appears to be possible to change a state in which magnesium ions can be present to a state in which Mg(OH)₂ precipitates out of solution. Moreover, by using an aqueous ammonia solution as the aqueous solution containing zinc ions and magnesium ions, the ammonia volatilizes with increasing ease as the temperature of the aqueous solution is increased, enabling the pH of the aqueous ammonia solution to be progressively lowered as the ammonia volatilizes. Hence, it is thought that raising the temperature of the aqueous ammonia solution causes the aqueous ammonia solution to change from a state on the high pH side of line α (a state in which ZnO₂²⁻ could exist) to a state on the low pH side of line α′ (a state in which Zn(OH)₂ precipitates out).

That is, because it becomes possible, by elevating the temperature of the aqueous ammonia solution after ZnO₂²⁻ and magnesium ions have both been made present in the solution, to induce the precipitation of Zn(OH)₂ and Mg(OH)₂ under a similar timing, it appears to be possible to produce a ZnMgO film in which the amount of magnesium addition with respect to zinc has been increased to at least 30 mol %. The invention was ultimately achieved on the basis of this finding.

Embodiments of the invention are described below while referring to the diagrams. It should be noted that although the embodiments shown below are examples of the invention, the invention is not limited to these embodiments.

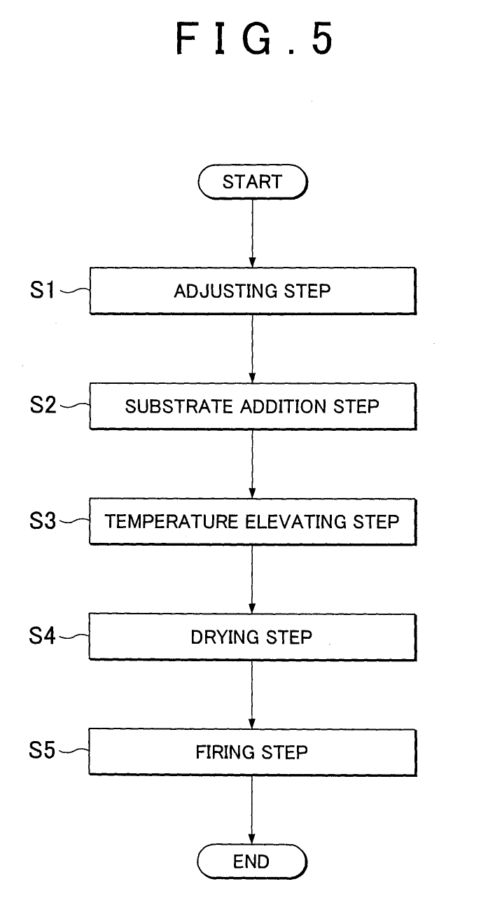

FIG. 5 is a flow diagram illustrating a ZnMgO film manufacturing method according to an embodiment of the invention (which method is sometimes referred to below as “the manufacturing method of the embodiment”). As shown in FIG. 5, the ZnMgO film manufacturing method of the embodiment has an adjusting step (S1), a substrate addition step (S2), a temperature elevating step (S3), a drying step (S4), and a firing step (S5).

The adjusting step (sometimes referred to below as “S1”) is the step of dissolving a zinc material and a magnesium material in an aqueous ammonia solution having a temperature at which, in an aqueous solution state diagram which represents a zinc ion concentration and a magnesium ion concentration on a vertical axis and represents pH on a horizontal axis, a line α is positioned on the low pH side of a line β, and adjusting the pH of the aqueous ammonium solution and the zinc ion concentration and magnesium ion concentration within the aqueous ammonia solution so as to achieve an aqueous solution state in a region lying between line α and line β. That is, when the temperature of the aqueous ammonia solution is 25° C., S1 is the step of dissolving a zinc material and a magnesium material in the aqueous ammonia solution, and adjusting the pH, the zinc ion concentration and the magnesium ion concentration so that the solution state falls in the region lying between line α and line β in FIG. 2.

The substrate addition step (sometimes referred to below as “S2”) is the step of, following S1, placing the substrate on which the ZnMgO film is to be formed within a vessel containing the aqueous ammonia solution.

The temperature-elevating step (sometimes referred to below as “S3”) is the step of, following S2, elevating the temperature of the aqueous ammonia solution to a temperature at which Zn(OH)₂ and Mg(OH)₂ precipitate out of solution. As mentioned above, by elevating the temperature of the aqueous ammonia solution, it is possible to volatilize the ammonia and lower the pH of the aqueous ammonia solution. Hence, it is possible to change an aqueous ammonia solution that was set in a state where ZnO₂²⁻ can exist to a state in which Zn(OH)₂ precipitates out of solution. Also, as mentioned above, because line β can be shifted to the low pH side by elevating the temperature of the aqueous ammonia solution, it is possible to change an aqueous ammonia solution that was set in a state where magnesium ions can exist to a state in which Mg(OH)₂ precipitates out. That is, S3 is the step of inducing ZnO₂²⁻ to precipitate out as Zn(OH)₂ and inducing magnesium ions to precipitate out as Mg(OH)₂.

The drying step (sometimes referred to below as “S4”) is the step of drying the precipitate (a mixture of Zn(OH)₂ and Mg(OH)₂) that was induced to precipitate out of solution in S3.

The firing step (sometimes referred to below as “S5”) is the step of, following S4, firing the precipitate that has been dried. By passing through S5, a dehydration reaction is induced, enabling a ZnMgO film to be produced. The firing temperature in S5 should be a temperature at which a dehydrating reaction arises and weight loss by the precipitate is confirmed. For example, the firing temperature may be set to at least 200° C. and at most 350° C. The firing time in S5 is not particularly limited, and may be set to about the same time as in conventional liquid phase film-forming processes.

By passing through S1 to S5, it is possible to have Zn(OH)₂ and Mg(OH)₂ precipitate out of solution at a similar timing, thus making it possible to produce a ZnMgO film in which the amount of magnesium addition relative to the zinc has been elevated to at least 30 mol %.

In this embodiment, chlorides, nitrates, sulfates, acetates and the like of zinc and magnesium may be suitably used as the zinc material and the magnesium material.

In this embodiment, the form of S1 is not particularly limited, so long as it is a step of dissolving a zinc material and a magnesium material in an aqueous ammonia solution having a temperature at which line α is positioned on the low pH side of line β, and adjusting the pH of the aqueous ammonium solution and the zinc ion concentration and magnesium ion concentration within the aqueous ammonia solution so as to achieve an aqueous solution state in a region lying between line α and line β. However, from the standpoint of, for example, having this step take a form that facilitates the dissolution of the zinc starting material and, the magnesium starting material and thus enables the time required for S1 to be shortened, it is preferable for S1 to take the form of dissolving the zinc material and the magnesium material in an aqueous ammonia solution that is being stirred.

In S1, no particular limitation is imposed on the manner in which the zinc material and the magnesium material are dissolved in the aqueous ammonia solution at a temperature at which line α is positioned on the low pH side of line β. S1 may take a form in which the temperature is changed (e.g., the temperature is lowered) after the zinc material and the magnesium material have been dissolved in an aqueous ammonia solution. Alternatively, S1 may take a form in which the temperature of the aqueous ammonia solution is set to a temperature at which line α is positioned on the low pH side of line β, following which the zinc material and the magnesium material are dissolved in the aqueous ammonia solution.

Also, in S1, the temperature at which line α is positioned on the low pH side of line β may be set to, for example, below 30° C. As mentioned above, because the degree of shift to the low pH side upon raising the temperature is larger for line β than for line α, it is thought that the degree of shift to the high pH side upon lowering the temperature of the aqueous ammonia solution also is larger for line β than for line α. The lower the temperature to which the aqueous ammonia solution is set, the wider the region lying between line α and line β can be made. As a result of this, the aqueous ammonia solution becomes easy to adjust within the region lying between line α and line β. Therefore, from the standpoint of, for example, taking a form that facilitates adjustment in a range lying between line α and line β and enables a ZnMgO film to be easily produced, it is preferable in S1 to set the temperature at which line cc is positioned on the low pH side of line β to at most 25° C. The temperature is more preferably at most 5° C.

Alternatively, in this embodiment, the substrate which may be used in S2 is not particularly limited, provided it is able to withstand the firing temperature in S5 and a ZnMgO film can be formed on the surface thereof. Examples of such materials capable of making up the substrate include quartz glass, a stainless steel substrate and a soda lime glass substrate.

Also, in this embodiment, the temperature to which the aqueous ammonia solution can be raised in S2 is not particularly limited, provided it is a temperature at which Zn(OH)₂ and Mg(OH)₂ are capable of precipitating out of solution. In order to induce the precipitation of Zn(OH)₂ and Mg(OH)₂, it is preferable to set the temperature of the aqueous ammonia solution to, for example, at least 30° C. From the standpoint of, for example, preventing a large fluctuation in the ion concentration and drying out of the aqueous solution it is preferable to set the temperature of the aqueous ammonia solution to at most 80° C. The temperature of the aqueous ammonia solution is more preferably at least 40° C. and at most 60° C.

The form that S2 takes is not particularly limited, provided that, along with inducing ZnO₂²⁻ to precipitate out as Zn(OH)₂, magnesium ions can be induced to precipitate out as Mg(OH)₂. However, from the standpoint of, for example, having S2 take a form where Zn(OH)₂ and Mg(OH)₂ readily precipitate, it is preferable to have S2 be in a form that elevates the temperature of the aqueous ammonia solution being stirred, thereby inducing the precipitation of Zn(OH)₂ and Mg(OH)₂.

After placing 180 mL of water and 5 to 30 mL of 10% ammonia water in a beaker, the beaker was immersed in ice-water and cooled until the temperature of the aqueous ammonia solution reached 5° C. In a separate operation, a zinc material (zinc acetate) and a magnesium material (magnesium acetate) were weighed out in molar ratios of zinc acetate to magnesium acetate of 6:4, 7:3, 8:2, 9:1 and 1:0, then added to the beaker. Next, a rotor was placed in the beaker and the contents of the beaker were thoroughly stirred on a stirrer, thereby dissolving the zinc acetate and the magnesium acetate. With the exception of the example (condition) in which magnesium acetate was not used, the aqueous ammonia solution following the dissolution of zinc acetate and magnesium acetate was adjusted to a state that falls in the region lying between line α and line β. After the zinc acetate and magnesium acetate were dissolved, a quartz glass substrate was placed in the beaker. Then, while stirring the aqueous ammonia solution, the beaker was immersed in a water bath heated to 60° C. and held therein for 30 minutes. The quartz glass substrate was then taken out and dried, and subsequently fired in the open air at 500° C. for 1 hour. By passing through the above step, a film (a ZnO film when magnesium acetate was not used, and a ZnMgO film when magnesium acetate was used; the same applies below) was produced.

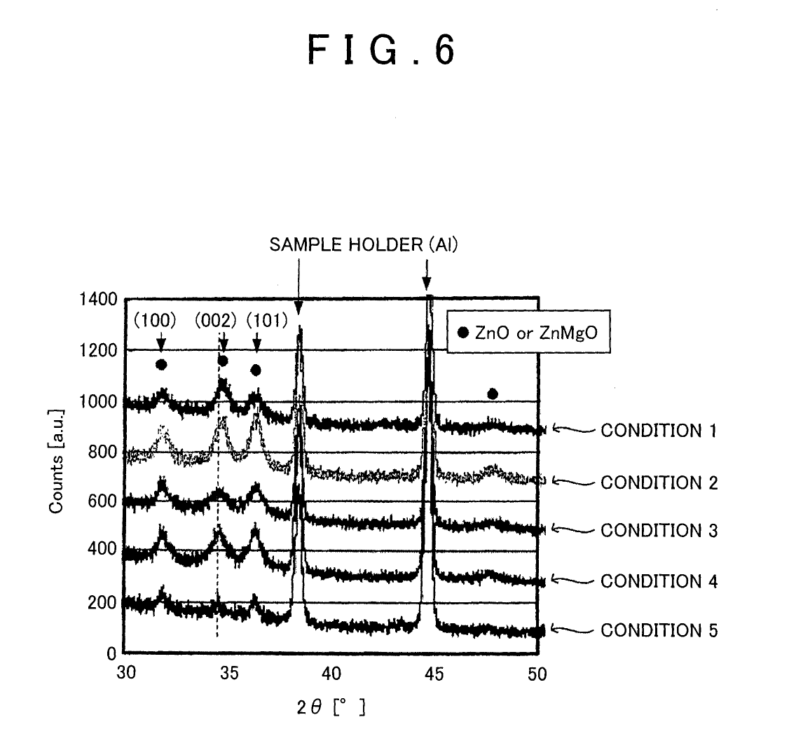

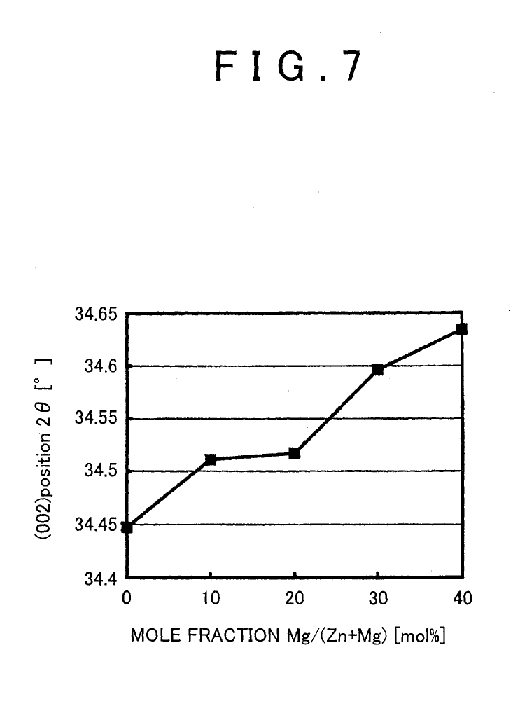

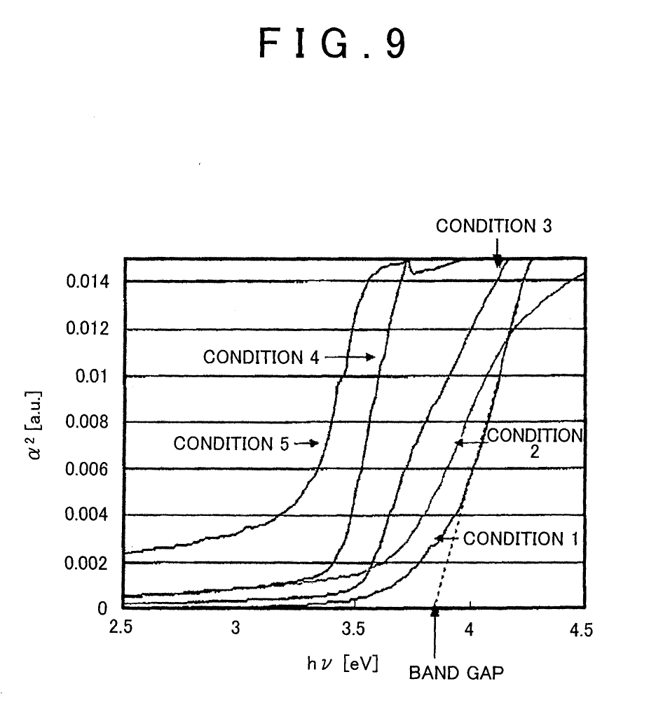

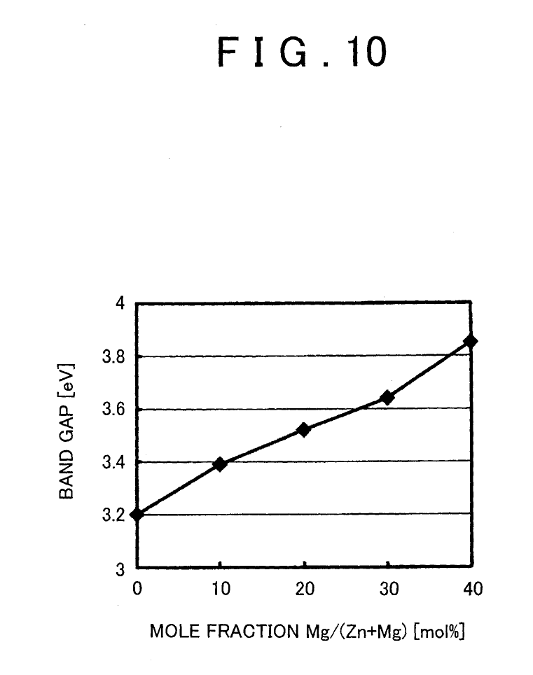

X-ray diffraction analysis was carried out using an x-ray diffractometer (Smart-Lab, from Rigaku Corporation). The results are shown in FIGS. 6 and 7, and in Table 1. In FIG. 6, the vertical axis represents the count in atomic units (a.u.), and the horizontal axis represents the diffraction angle 2 θ in degrees) (°). FIG. 7 is a graph showing the relationship between the mole fraction Mg/(Zn+Mg) (mol %) and the diffraction angle 2 θ (°) at which a (002) peak was confirmed in x-ray diffraction analysis. In FIG. 7, the vertical axis represents the diffraction angle 2 θ (°) at which the (002) peak was confirmed, and the horizontal axis represents the mole fraction Mg/(Zn+Mg) (mol %). Also, the band gaps of the films produced were determined by measuring the light absorption coefficient using an ultraviolet-visible spectrophotometer (V-570, from JASCO Corporation). The band gap results are shown in Table 1 and in FIGS. 9 and 10. In FIG. 9, the vertical axis represents the square of the light absorption coefficient a in atomic units (a.u.), and the horizontal axis represents the energy hv in electron volts (eV). The band gaps were determined from lines extrapolated from the spectrum. In FIG. 10, the vertical axis represents the band gap (eV), and the horizontal axis represents the mole fraction Mg/(Zn+Mg) (mol %). In Table 1, the amount of magnesium in solid solution (mol %) was determined from formula (1) below.

Amount of magnesium in solid solution (mol %)=(band gap−3.2)/0.02 formula (1)

TABLE 1

| | | X-ray | | |
|---|---|---|---|---|
| | mole | diffraction | | Amount of |
| | fraction | (002) peak | Band | Mg in solid |
| | Mg/(Zn + Mg) | position | gap | solution |
| | (mol %) | (°) | (eV) | (mol %) |
| Condition 1 | 0.4 | 34.634 | 3.85 | 32.5 |
| Condition 2 | 0.3 | 34.596 | 3.64 | 22 |
| Condition 3 | 0.2 | 34.517 | 3.52 | 16 |
| Condition 4 | 0.1 | 34.511 | 3.39 | 9.5 |
| Condition 5 | 0 | 34.447 | 3.20 | 0 |

As shown in FIGS. 6 and 7, an increase in the proportion of material magnesium was accompanied by a shift in the (002) diffraction peak to the high-angle side. This was presumably because magnesium having an ionic radius of 0.65 Å was substituted at zinc (ionic radius, 0.74 Å) sites, resulting in shrinkage of the crystals in the C axis direction. From these x-ray diffraction measurement results, the films obtained under Conditions 1 to 4 were determined to be ZnMgO films.

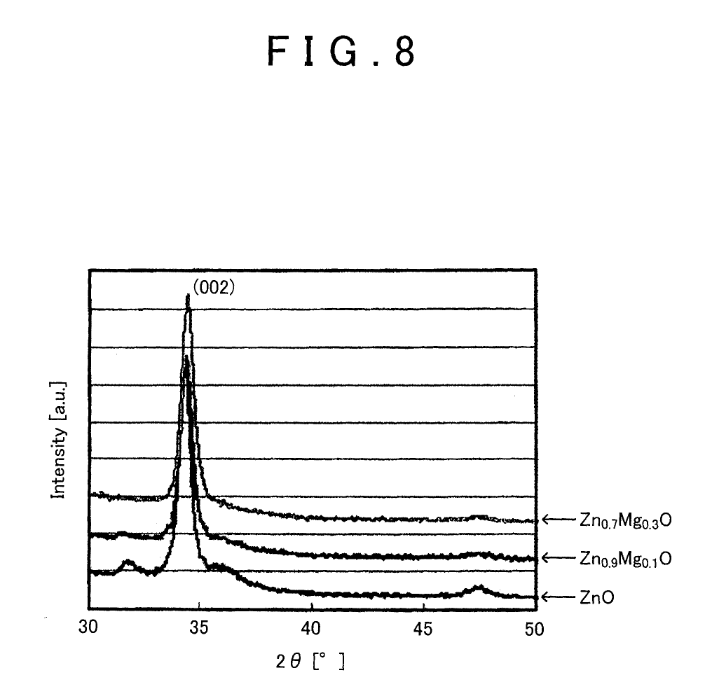

FIG. 8 shows the x-ray diffraction measurement results for the ZnMgO films produced by a sputtering process. In FIG. 8, the vertical axis represents the intensity (a.u.) and the horizontal axis represents the diffraction angle 2 θ (°). In FIG. 8, only a (002) peak is observed, indicating that the film is oriented in the (002) crystal plane. On the other hand, films produced by the manufacturing method of this embodiment, as shown in FIG. 6, are not oriented in the (002) crystal plane and have a ratio of (100) x-ray diffraction intensity to (002) x-ray diffraction intensity of at least ½ and a ratio of (101) x-ray diffraction intensity to (002) x-ray diffraction intensity of at least ½.

As shown in FIGS. 9 and 10, a rise in the ratio of the material magnesium is accompanied by an increase in the size of the band gap. The amount of magnesium in solid solution in the crystals can be calculated from the band gap using above formula (1). Because the band gap under Condition 1 is. 3.85 eV, using formula (1), the amount of magnesium in solid solution in this film is 32.5 mol %. This embodiment is thus able to provide a ZnMgO film manufacturing method which can set the amount of magnesium in solid solution with respect to zinc to at least 30 mol %, and is able to provide a ZnMgO film in which the amount of magnesium added with respect to zinc is at least 30 mol %.

1. A method of manufacturing a ZnMgO film, comprising the steps of:
dissolving a zinc material and a magnesium material in an aqueous ammonia solution having a temperature at which, in an aqueous solution state diagram which represents a zinc ion concentration and a magnesium ion concentration on a vertical axis and represents pH on a horizontal axis, a line α demarcated by a region where Zn(OH)₂ precipitates and a region where ZnO₂²⁻ can exist is positioned on a lower pH side than a line 1E demarcated by a region where magnesium ions can exist and a region where Mg(OH)₂ precipitates, and adjusting the pH of the aqueous ammonia solution and the zinc ion concentration and magnesium ion concentration within the aqueous ammonia solution so as to obtain a state within a region lying between the line α and line β;
elevating the temperature of the aqueous ammonia solution to a temperature at which Zn(OH)₂ and Mg(OH)₂ precipitate after the pH and the ion concentrations are adjusted; and
firing the precipitate after the temperature of the aqueous ammonia solution is elevated.

2. The ZnMgO film manufacturing method according to claim 1, wherein the temperature at which the line α is positioned on the lower pH side than the line β is at most 25° C.

3. The ZnMgO film manufacturing method according to claim 1, wherein the temperature at which the Zn(OH)₂ and the Mg(OH)₂ precipitate is at least 25° C. and at most 80° C.

4. A ZnMgO film having a ratio of (100) x-ray diffraction intensity to (002) x-ray diffraction intensity of at least ½, and a ratio of (101) x-ray diffraction intensity to (002) x-ray diffraction intensity of at least ½.

5. A ZnMgO film produced by the manufacturing method according to claim 1.

6. The ZnMgO film of claim 5, wherein the film has a ratio of (100) x-ray diffraction intensity to (002) x-ray diffraction intensity of at least ½ and a ratio of (101) x-ray diffraction intensity to (002) x-ray diffraction intensity of at least ½.
